(19) United States
(12) Patent Application Publication
(10) Pub. No.: US 2025/0204192 A1
(43) Pub. Date: Jun. 19, 2025

(54) Light Emitting Display Device Having Improved Luminescent Property

(71) Applicant: LG Display Co., Ltd., Seoul (KR)

(72) Inventors: June-Hwan Kim, Paju-si (KR); Hyun-Woo Jeon, Paju-si (KR); Young-Min Oh, Paju-si (KR)

(21) Appl. No.: 18/904,114

(22) Filed: Oct. 2, 2024

(30) Foreign Application Priority Data
Dec. 15, 2023 (KR) 10-2023-0183107

(51) Int. Cl. H10K 59/38; H10K 50/115; H10K 59/35; H10K 59/80

(52) U.S. Cl. CPC H10K 59/38; H10K 50/115; H10K 59/351; H10K 59/877; H10K 59/879; H10K 59/8791

(57) ABSTRACT

A light emitting display device comprises a light reduction lens disposed in one or more pixel areas and disposed on light emitting diodes, and optionally, a light intensification lens disposed on other pixel areas and disposed on a color correction pattern. The light reduction lens increases omnidirectional reflection visibility of the light emitting display device and blocks hazardous blue light. The light intensification lens increases the luminance of blue light of the display device. Even if a uniformly distributed phase retardation film is applied, the light emitting display device with beneficial reflection characteristics, color gamut, and luminance is realized.

### CROSS-REFERENCE TO RELATED APPLICATIONS

This application claims priority under 35 U.S.C. § 119(a) to the Republic of Korea Patent Application No. 10-2023-0183107, filed in the Republic of Korea on Dec. 15, 2023, the entire contents of which are hereby expressly incorporated by reference into the present application.

### BACKGROUND

### Technical Field

The present disclosure relates to a light emitting device, and more particularly to, a light emitting display device with beneficial luminous efficiency and color gamut.

### Discussion of Related Art

Flat display devices comprising a light emitting diode (LED) have been investigated as display devices that can replace a liquid crystal display device (LCD). The electrode configurations in the LED can implement unidirectional or bidirectional images. Also, the LED can be formed even on a flexible transparent substrate such as a plastic substrate so that a flexible or a foldable display device can be realized with ease using the LED. In addition, the LED can be driven at a lower voltage and the LED has advantageous high color purity compared to the LCD.

The LED emits light as holes injected from anode and electrons injected from cathode are recombined within an emitting material layer to generate excitons of unstable energy state, and the excitons convert to a stable ground state. The light emitting device using the LED comprises a polarizer to prevent reflection visibility from being lowered by external light. However, there is a need to develop a light emitting device with improved the reflection visibility and luminescent property.

### SUMMARY OF THE DISCLOSURE

Accordingly, some embodiments of the present disclosure are directed to a light emitting display device that substantially obviates one or more of the problems due to the limitations and disadvantages of the related art.

An aspect of the present disclosure is to provide a light emitting display device with beneficial visibility and reflection property.

Another aspect of the present disclosure is to provide a light emitting display device with lowering hazard blue light amount, and beneficial luminance and color gamut.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a light emitting display device that comprises a light emitting diode disposed at each of emission areas of a first pixel region, a second pixel region, a third pixel region and a fourth pixel region; a color correction pattern where light emitted from the light emitting diode respectively disposed in the first pixel area, the second pixel area and the third pixel area; a light reduction lens located in a direction in which light from the light emitting diode disposed in the fourth pixel area is emitted; a substrate disposed in a direction in which light from the light emitting diode is emitted relative to the color correction pattern and the light reduction lens; and a polarizer disposed on an outer surface of the substrate and comprising an uniform dispersion phase retardation film, wherein the light reduction lens has a shape protruding from the light emitting diode disposed in the fourth pixel region toward the substrate.

The light reduction lens can comprise a material with a refractive index of about 1.30 to about 1.50.

The light emitting display device can further comprise a light intensification lens disposed between the color correction pattern disposed respectively to the third pixel region and the substrate and has a shaped protruding from the color correction pattern disposed in the third pixel region toward the substrate.

The light intensification lens can comprise a material with a refractive index of about 1.65 to about 2.50.

The light intensification lens can have a semicircular shape or a semielliptical shape protruding the color correction film disposed respectively to the third pixel region toward the substrate.

The uniform dispersion phase retardation film can comprise at least one of a quarter wave plate (QWP) and a half wave plate (HWP).

The polarizer can further comprise a linear polarizer attached on the uniform dispersion phase retardation film.

The linear polarizer can comprise a polarizing film; and a first protective film and a second protective film disposed on both sides of the polarizing film.

The polarizer can further comprise a first adhesive layer disposed between the linear polarizer and the uniform dispersion phase retardation film; and a second adhesive layer disposed between the uniform dispersion phase retardation film and the substrate.

In one embodiment, at least one of the first adhesive layer and the second adhesive layer can comprise light scattering particles.

In another embodiment, the uniform dispersion phase retardation film can comprise light scattering particles.

For example, the light scattering particles are chosen from ZrO₂, TiO₂, Al₂O₃, ZnO, MgO, Indium-tin-oxide (ITO), aluminum-zinc-oxide (AZO), SiO₂, and combinations thereof.

The light emitting diode can comprise a first electrode; a second electrode facing the first electrode; and an emissive layer disposed between the first electrode and the second electrode, wherein the emissive layer can comprise one or more emitting material layers.

In one embodiment, the one or more emitting material layer can comprise organic emission material.

In another embodiment, the one or more emitting material layer can comprise inorganic luminescent particles.

As an example, the light emitting display device can further comprise a thin film transistor disposed on the substrate respectively to each of non-emission areas of the first pixel region, the second pixel region, the third pixel region, and the fourth pixel region, and connected to the light emitting diode respectively to the first pixel region, the second pixel region, the third pixel region, and the fourth pixel region.

For example, the first pixel region can be a red pixel region, the second pixel region can be a green pixel region, the third pixel region can be a blue pixel region, and the fourth pixel region can be a white pixel region.

In one embodiment, the color correction pattern can be a color filter pattern comprising one or more colorants.

In another embodiment, the color correction pattern can be a color conversion pattern comprising inorganic luminescent particles such as quantum dots and quantum rods.

The light reduction lens can have a semicircular shape or a semielliptical shape protruding the light emitting diode toward the substrate.

In one or more embodiments, the light reduction lens protruded toward light emission direction is disposed on the light emitting diode, and disposed correspondingly in one or more pixel regions, and optionally, the light intensification lens protruded toward the light emission direction is disposed on the color correction film disposed respectively to other pixel region in the light emitting display device.

Owing to the light reduction lens, the amount of hazard blue light emitted from the light emitting diode can be lowered and the omnidirectional reflection visibility of the uniform dispersion phase retardation film can be increased. Owing to the light intensification lens, the blue light luminance can be increased. Owing to the light scattering particles in one or more films in the polarizer, the frontal visibility of the display device can be improved.

Accordingly, the light emitting display device with blocking or lowering efficiently hazard blue light amount and with beneficial luminance, correlation color temperature and color gamut can be implemented. In addition, the fabrication cost of the light emitting display device can be lowered by applying the uniform dispersion phase retardation film instead of expensive reverse dispersion phase retardation film.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic circuit diagram of a light emitting display device in accordance with one or more embodiments of the present disclosure.

FIG. 2 illustrates a cross-sectional view of a light emitting display device in accordance with an embodiment of the present disclosure.

FIG. 3 illustrates a cross-sectional view of a light emitting diode having multiple emitting parts in accordance with an embodiment of the present disclosure.

FIG. 4 is a cross-sectional view illustrating a laminated structure of a polarizer in accordance with an embodiment of the present disclosure.

FIG. 5 illustrates a cross-sectional view of a light emitting display device in accordance another embodiment of the present disclosure.

FIG. 6 is a cross-sectional view illustrating a laminated structure of a polarizer in accordance with another embodiment of the present disclosure.

Each of FIGS. 7 to 9 illustrates omnidirectional visibility in light emitting display devices fabricated in Example or Comparative Example.

Each of FIGS. 10 and 11 illustrates frontal visibility in light emitting display devices fabricated in Example or Comparative Example.

FIG. 12 is a graph illustrating whole light wavelengths measured in light emitting display device fabricated in Example or Comparative Example.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts.

All the components of each light emitting display device according to all embodiments of the present disclosure are operatively coupled and configured.

The present disclosure relates to a light emitting display device that comprises a light reduction lens, and optionally, a light intensification lens each of which can control or regulate amount of light emitted from one or more light emitting diode disposed respectively to an emission area in a portion of pixel regions.

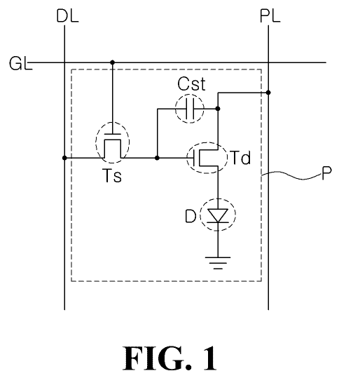

FIG. 1 illustrates a schematic circuit diagram of a light emitting display device in accordance with one or more embodiments of the present disclosure.

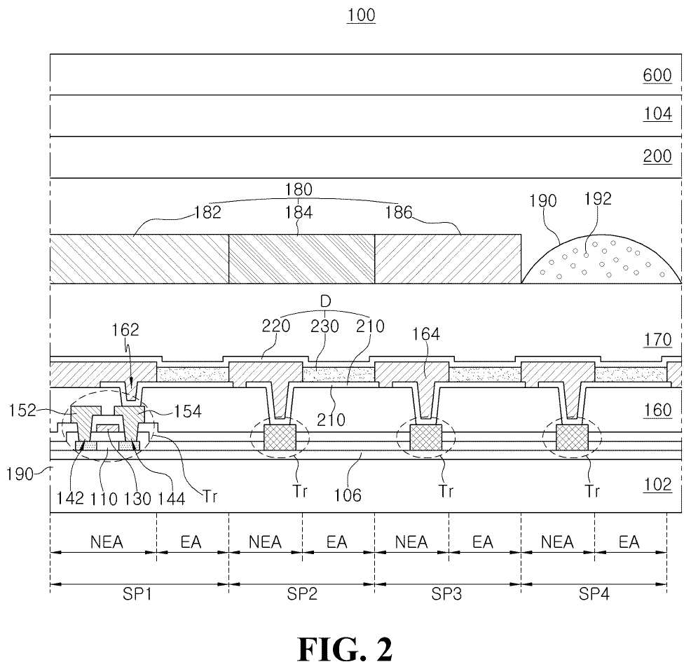

As illustrated in FIG. 1, a gate line GL, a data line DL and power line PL, each of which crosses each other to define a pixel region P, are provided in a light emitting display device. A switching thin film transistor Ts, a driving thin film transistor Td, a storage capacitor Cst and a light emitting diode D are disposed within the pixel region P. The pixel region P can comprise a first pixel region SP1 (FIG. 2), a second pixel region SP2 (FIG. 2) and a third pixel region SP3 (FIG. 2), and optionally a fourth pixel region SP4 (FIG. 2). However, embodiments of the present disclosure are not limited to such examples. The light emitting display device can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

The driving thin film transistor Td is turned on by the data signal applied to a gate electrode 130 (FIG. 2) so that a current proportional to the data signal is supplied from the power line PL to the light emitting diode D through the driving thin film transistor Td. And then, the light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the light emitting display device can display a desired image.

FIG. 2 illustrates a schematic cross-sectional view of a light emitting display device in accordance with an embodiment of the present disclosure. The pixel circuit configuration of FIG. 1 can be used in the display device of FIG. 2 or other figures of the present application.

As illustrated in FIG. 2, the light emitting display device 100 comprises a first substrate 102 and a second substrate (or encapsulation film) 104 facing the first substrate 102. The first to fourth pixel regions SP1, SP2, SP3 and SP4 are defined in the first substrate 102 and/or the second substrate 104. Each of the first pixel region SP1, the second pixel region SP2, the third pixel region SP3 and the fourth pixel region SP4 can be divided into an emission area EA where a light emitting diode D and a color correction pattern 180 are disposed, and a non-emission area NEA where a thin film transistor Tr is disposed. As an example, each of the first pixel region SP1, the second pixel region SP2, the third pixel region SP3 and the fourth pixel region SP4 can be a red (R) pixel region, a green (G) pixel region, a blue (B) pixel region and a white (W) pixel region, respectively.

A thin film transistor Tr and a light emitting diode D are disposed on the first substrate 102 in the first to fourth pixel regions SP1, SP2, SP3 and SP4 to from an array panel. I addition, the color correction pattern 180 can be disposed in the emission area EA under the second substrate 104 defining the first to third pixel regions SP1, SP2 and SP3.

Each of the first substrate 102 and the second substrate 104 can include a transparent material. For example, each of the first substrate 102 and the second substrate 104 can be a glass substrate, a flexible substrate, a polymer plastic substrate or a metal foil. As an example, the flexible substrate can include, but is not limited to, polyimide (PI), polyethersulfone (PES), polyethylenenaphthalate (PEN), polyethylene terephthalate (PET), polycarbonate (PC) and combinations thereof.

A buffer layer 106 can be disposed on the first substrate 102 in the first to fourth pixel regions SP1, SP2, SP3 and SP4. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can comprise, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can comprise polycrystalline silicon. In this case, opposite edges of the semiconductor layer 110 can be doped with impurities.

A gate insulating layer 120 comprising an insulating material is disposed on the semiconductor layer 110. The gate insulating layer 120 can comprise, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the first substrate 102 as shown in FIG. 2, the gate insulating layer 120 can be patterned identically as the gate electrode 130.

An interlayer insulating layer 140 comprising an insulating material is disposed on the gate electrode 130 and covers an entire surface of the first substrate 102. The interlayer insulating layer 140 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 and the interlayer insulating layer 140 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon.

The light emitting diode D is electrically connected to the thin film transistor Tr as a driving element in the first to fourth pixel regions SP1, SP2, SP3 and SP4. In addition, the switching thin film transistor Ts (FIG. 1) electrically connected to the thin film transistor Tr, the gate line GL (FIG. 1) and the data line DL (FIG. 1), and the storage capacitor Cst (FIG. 1) electrically connected to the switching thin film transistor Ts and the power line PL (FIG. 1) are disposed on the first substrate 102 in the first to fourth pixel regions SP1, SP2, SP3 and SP4.

When the switching thin film transistor Ts is turned on by a gate signal applied to the gate line GL, a data signal applied to the data line DL is applied to the gate electrode 130 of the thin film transistor Tr as the driving element and one electrode of the storage capacitor Cst through the switching thin film transistor Ts. The thin film transistor Tr is turned on by the data signal applied to the gate electrode 130 so that a current proportional to the data signal is supplied from the power line PL to the light emitting diode D through the thin film transistor Tr of the driving element. And then, the light emitting diode D emits light having a luminance proportional to the current flowing through the thin film transistor Tr.

A first passivation layer 160 is disposed on the source and drain electrodes 152 and 154. The first passivation layer 160 covers the thin film transistor Tr on the entire first substrate 102. The passivation layer 160 has a flat top surface and a drain contact hole (or a contact hole) 162 that exposes or does not cover the drain electrode 154 of the thin film transistor Tr.

The light emitting diode (LED) D comprises a first electrode 210 that is disposed on the first passivation layer 160 and connected to the drain electrode 154 of the thin film transistor Tr. The LED D further comprises an emissive layer 230 and a second electrode 220 each of which is disposed sequentially on the first electrode 210.

One of the first electrode 210 and the second electrode 220 can be an anode, and the other of the first electrode 210 and the second electrode 220 can be a cathode. One of the first electrode 210 and the second electrode 220 can be a reflective electrode, and the other of the first electrode 210 and the second electrode 220 can be a transmissive electrode.

The first electrode 210 is disposed separately in each pixel region SP1, SP2, SP3 or SP4. In one embodiment, the first electrode 210 can be an anode and comprise conductive material having relatively high work function value. For example, the first electrode 210 can comprise a transparent conductive oxide (TCO).

In one embodiment, when the light emitting display device 100 is a bottom-emission type, the first electrode 210 can have a single-layered structure of the TCO. Alternatively, when the light emitting display device 100 is a top-emission type, a reflective electrode or a reflective layer can be disposed under the first electrode 210. For example, the reflective electrode or the reflective layer can comprise, but is not limited to, silver (Ag) or aluminum-palladium-copper (APC) alloy. As an example, in the LED D of the top-emission type, the first electrode 210 can have a triple-layered structure of ITO/Ag/ITO or ITO/APC/ITO.

In addition, a bank layer 164 is disposed on the first passivation layer 160 in order to cover edges of the first electrode 210. The bank layer 164 exposes or does not cover a center of the first electrode 210 corresponding to each pixel region SP1, SP2, SP3 or SP4. In certain embodiments, the bank layer 164 can be omitted.

An emissive layer 230 is disposed on the first electrode 210. In one embodiment, the emissive layer 230 can have a single-layered structure of an emitting material layer (EML). In one embodiment, the EML can comprise organic emitting materials such as host and/or dopant. In another embodiment, the EML can comprise inorganic luminescent particles such as quantum dots (QDs) and quantum rods (QRs). For example, the organic dopant can comprise phosphorescent material, fluorescent material and/or delayed fluorescent material emitting red (R) color, green (G) color and blue (B) color. The LED D can emit white (W) color.

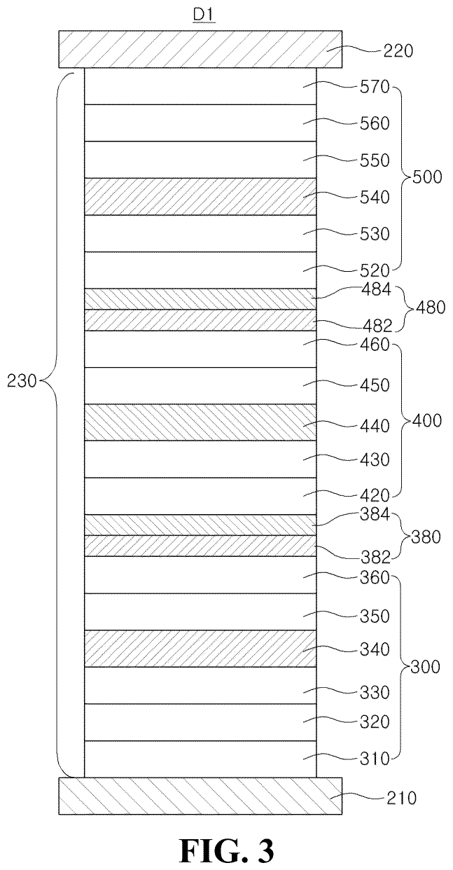

In another embodiment, the emissive layer 230 can have a multiple-layered structure. For example, the emissive layer 230 can further comprise a hole injection layer (HIL), a hole transport layer (HTL) and/or an electron blocking layer (EBL) disposed sequentially between the first electrode 210 and the EML, and/or a hole blocking layer (HBL), an electron transport layer (ETL), an electron injection layer (EIL) and/or a charge generation layer (CGL) disposed between the EML and the second electrode 210 (FIG. 3). Two or more emitting parts of the emissive layer 230 can form a tandem structure (FIG. 3), or the emissive layer 230 can consist of a single emitting part.

The second electrode 220 is disposed on the first substrate 102 above which the emissive layer 230 is disposed. The second electrode 220 can be disposed on the entire display area. The second electrode 220 can comprise a conductive material with a relatively low work function value compared to the first electrode 210. When the light emitting display device 100 is a top-emission type, the second electrode 220 is thin so as to have light-transmissive (semi-transmissive) property.

In addition, an adhesive layer 170 can be disposed on the LED D in order to prevent or reduce outer moisture from penetrating into the LED D. The adhesive layer 170 can comprise, but is not limited to, an optically clear adhesive (OCA) and a pressure sensitive adhesive (PSA).

The color correction pattern 180 is disposed on the adhesive layer 170 correspondingly to the first to third pixel regions SP1, SP2 and SP3. A light reducing lens 190 is disposed on the adhesive layer 170 correspondingly to the fourth pixel region SP4.

The color correction pattern 180 can comprise a first color correction pattern 182 disposed correspondingly the first pixel region SP1 (e.g., emission area EA), a second color correction pattern 184 disposed correspondingly to the second pixel region SP2 (e.g., emission area EA), and a third color correction pattern 186 disposed correspondingly to the third pixel region SP3 (e.g., emission area EA).

In one embodiment, the color correction pattern 180 can comprise one or more colorants. The color correction pattern 180 can be a color filter pattern transmitting a portion of light emitted from the light emitting diode D disposed in the emission areas EAs of the first to third pixel regions SP1, SP2 and SP3, respectively. For example, the first color correction pattern 182 can comprise one or more red pigments and/or one or more red dyes, the second color correction pattern 184 can comprise one or more green pigments and/or one or more green dyes, and the third color correction pattern 186 can comprise one or more blue pigments and/or one or more blue dyes.

In another embodiment, the color correction pattern 180 can comprise inorganic luminescent particles such as quantum dots (QDs) and/or quantum rods (QRs). The color correction pattern 182 can be a color conversion pattern converting a portion of light emitted from the light emitting diode D disposed in the emission areas EAs of the first to third pixel regions SP1, SP2 and SP3, respectively. For example, the first color correction pattern 182 can comprise red quantum dots and red quantum rods, the second color correction pattern 184 can comprise green quantum dots and green quantum rod, and the third color correction pattern 186 can comprise blue quantum dots and blue quantum rods.

The light reduction lens 192 can comprise a low-refractive material 192 with a refractive index of about 1.30 to about 1.50, for example, about 1.40 to about 1.50 or about 1.45 to about 1.47. At least a portion of blue (B) light emitted from the third color correction pattern 186 can be totally reflected in the light reduction lens 190 comprising the low-refractive material 192. The light reduction lens 192 can have a shape that protrudes from the light emitting diode D toward a light emission direction, i.e., toward the second substrate 104. As an example, the light reduction lens 190 can have, but is not limited to, a semicircular shape or a semielliptical shape that protrudes toward to the second substrate 104 form the light emitting diode D. The light reduction lens 190 enables hazard blue light to be blocked or reduced.

As an example, the low-refractive material 192 in the light reduction lens 190 can comprise, but is not limited to, poly(methyl methacrylate (PMMA), polyvinyl alcohol (PVA), poly(tetrafluoroethylene), poly(heptafluorobutylacrylate), poly(octafluoropentylacrylate), poly(dimethyl siloxane) (PDMS), poly(ethylene oxide) (PEO), poly(vinyl-n-octylacrylate), poly(t-butlymethacrylate), poly(ethylacrylate), poly(n-butylacrylate), poly(methylacrylate), poly(ethylacrylate), and combinations thereof.

A second passivation layer 200 is disposed on the color correction pattern 180 and the light reduction lens 190 with covering the entire surface of the first substrate 102. The second substrate 104 is disposed on the second passivation layer 200, and a polarizer 600 is disposed on the second substrate 104.

In another embodiment, an encapsulation film can be disposed on the adhesive layer 170 with covering the entire surface of the first substrate 102. For example, the encapsulation film can have, but is not limited to, a lamination structure of a first inorganic insulation layer, an organic insulation layer and a second inorganic insulation layer. In certain embodiment, the encapsulation film can be omitted.

In addition, a cover window can be attached to the second substrate 104 in the top-emission type light emitting display device 100. In this case, the first substrate 102 and the cover window can have a flexible property, thus the light emitting display device 100 can be a flexible display device.

The LED can be used in the light emitting display device in the first embodiment is described in more detail. FIG. 3 illustrates a schematic cross-sectional view of a light emitting diode having multiple emitting parts in accordance with an embodiment of the present disclosure. For instance, FIG. 3 shows an example (LED D1) of the LED D in FIGS. 1 and 2.

As illustrated in FIG. 3, the light emitting diode D1 in accordance with an example of the present disclosure comprises first and second electrodes 210 and 220 facing each other and an emissive layer 230 disposed between the first and second electrodes 210 and 220. The light emitting diode (LED) D1 can be disposed in the first to fourth pixel regions SP1, SP2, SP3 and SP4, and emits white (W) light.

One of the first electrode 210 and the second electrode 220 can be an anode, and the other of the first electrode 210 and the second electrode 220 can be a cathode. As an example, the first electrode 210 can be an anode and the second electrode 220 can be a cathode. One of the first electrode 210 and the second electrode 220 can be a transmissive electrode, and the other of the first electrode 210 and the second electrode 220 can be a reflective electrode.

The first electrode 210 can comprise transparent conductive oxide (TCO) with relatively high work function. As an example, the first electrode 210 can comprise, but is not limited to, a doped or an undoped metal oxide such as indium-tin-oxide (ITO), indium-zinc-oxide (IZO), indium-tin-zinc-oxide (ITZO), tin oxide (SnO₂), indium oxide (In₂O₃), cadmium: zinc oxide (Cd: ZnO), fluorine: tin oxide (F: SnO₂), indium: tin oxide (In: SnO₂), gallium: tin oxide (Ga: SnO₂) and aluminum: zinc oxide (Al: ZnO; AZO). Alternatively or additionally, the first electrode 210 can comprise a metal material or a non-metal material such as nickel (Ni), platinum (Pt), gold (Au), silver (Ag), iridium (Ir) and/or carbon nanotube (CNT).

The second electrode 220 can comprise a metal or a metal halide with relatively low work function. As an example, the second electrode 220 can comprise, but is not limited to, calcium (Ca), barium (Ba), calcium/aluminum (Ca/Al), lithium fluoride/calcium (LiF/Ca), lithium fluoride/aluminum (LiF/Al), barium fluoride/aluminum (BaF₂/Al), cesium fluoride/aluminum (CsF/Al), calcium carbonate/aluminum (CaCO₃/Al), barium fluoride/calcium/aluminum (BaF₂/Ca/Al), aluminum (Al), magnesium (Mg), aluminum/magnesium (Al/Mg), gold: magnesium (Au: Mg) and/or silver: magnesium (Ag: Mg). For example, each of the first electrode 210 and the second electrode 220 can have a thickness of, but is not limited to, about 30 nm to about 300 nm.

The emissive layer 230 can comprise a first emitting part 300, a second emitting part 400 and a third emitting part 500. In addition, the emissive layer 230 can further comprise a first charge generation layer (CGL1) 380 disposed between the first emitting part 300 and the second emitting part 400, and a second charge generation layer (CGL2) 480 disposed between the second emitting part 400 and the third emitting part 500. Therefore, the second emitting part 300, the CGL1 380, the second emitting part 400, the CGL2 480 and the third emitting part 500 are laminated sequentially on the first electrode 210.

The first emitting part 300 can comprise a first emitting material layer (lower emitting material layer, EML1) 340. The first emitting part 300 can further comprise at least one of a hole injection layer (HIL) 310 disposed between the first electrode 210 and the EML1 340, a first hole transport layer (HTL1) 320 disposed between the HIL 310 and the EML1 340, and a first electron transport layer (ETL1) 360 disposed between the EML1 340 and the CGL1 380. Alternatively or additionally, the first emitting part 300 can further comprise at least one of a first electron blocking layer (EBL1) 330 disposed between the HTL1 320 and the EML1 340 and a first hole blocking layer (HBL1) 350 disposed between the EML1 340 and the ETL1 360.

The second emitting part 400 can comprise a second emitting material layer (middle emitting material layer, EML2) 440. The second emitting part 400 can further comprise at least one of a second hole transport layer (HTL2) 420 disposed between the CGL1 380 and the EML2 440, and a second electron transport layer (ETL2) 460 disposed between the EML2 440 and the CGL2 480. Alternatively or additionally, the second emitting part 400 can further comprise at least one of a second electron blocking layer (EBL2) 430 disposed between the HTL2 420 and the EML2 440 and a second hole blocking layer (HBL2) 450 disposed between the EML2 440 and the ETL2 460.

The third emitting part 500 can comprise a third emitting material layer (upper emitting material layer, EML3) 540. The third emitting part 500 can further comprise at least one of a third hole transport layer (HTL3) 520 disposed between the CGL2 480 and the EML3 540, a third electron transport layer (ETL3) 560 disposed between the EML3 540 and the second electrode 220, and an electron injection layer (EIL) 570 disposed between the ETL3 560 and the second electrode 220. Alternatively or additionally, the third emitting part 500 can further comprise at least one of a third electron blocking layer (EBL3) 530 disposed between the HTL3 520 and the EML3 540 and a third hole blocking layer (HBL3) 550 disposed between the EML3 50 and the ETL3 560.

The CGL1 380 is disposed between the first emitting part 300 and the second emitting part 400. In other words, the first emitting part 300 is connected to the second emitting part 400 through the CGL1 380. The CGL1 380 can be a PN-junction charge generation layer where a first N-type charge generation layer (N-CGL1) 382 is connected to a first P-type charge generation layer (P-CGL1) 384. The N-CGL1 382 is disposed between the ETL1 360 and the HTL2 420, and the P-CGL1 384 is disposed between the N-CGL1 382 and the HTL2 420.

The CGL2 480 is disposed between the second emitting part 400 and the third emitting part 500. In other words, the second emitting part 400 is connected to the third emitting part 500 through the CGL2 480. The CGL2 480 can be a PN-junction charge generation layer where a second N-type charge generation layer (N-CGL2) 482 is connected to a second P-type charge generation layer (P-CGL2) 484. The N-CGL2 482 is disposed between the ETL2 460 and the HTL3 520, and the P-CGL2 484 is disposed between the N-CGL2 482 and the HTL3 520.

In one embodiment, at least one of the EML1 340, the EML2 440 and the EML3 540 can be a blue emitting material layer, and at least another of the EML1 340, the EML2 440 and the EML3 540 can be a red to green emitting material layer. Hereinafter, the LED D1 where each of the EML1 340 and the EML3 540 is a blue emitting material layer, and the EML2 440 is a red to green emitting material layer will be described in detail.

The HIL 310 facilitates hole injections to the EML1 340 from the first electrode 210. Each of the HTL1320, the HTL2 420 and the HTL3 520 transfers holes to the EML1 340, the EML2 440 and the EML3 540, respectively. Each of the HTL1 320, the HTL2 420 and the HTL3 520 can independently comprise organic material or inorganic material.

In one embodiment, each of the EML1 340, the EML2 440 and the EML3 540 can independently organic emission material. For example, each of the EM11 340 and the EML3 540 can independently comprise organic emission material emitting blue color, and the EML2 440 can comprise organic emission material emitting red to green (if necessary yellow green) colors.

When the EML1 340 and the EML3 540 comprises the organic emission material, each of the EML1 340 and the EML3 540 can comprise a host and a blue dopant. The blue dopant can comprise at least one of blue phosphorescent material, blue fluorescent material and blue delayed fluorescent material.

When the EML2 440 comprises the organic emission material, the EML2 440 can comprise a host, a red dopant and a green dopant. The red dopant can comprise at least one of red phosphorescent material, red fluorescent material and red delayed fluorescent material. The green dopant can comprise at least one of green phosphorescent material, green fluorescent material and green delayed fluorescent material.

In another embodiment, each of the EML1 340, the EML2 440 and the EML3 540 can comprise inorganic luminescent particles. For example, the inorganic luminescent particles can comprise nano inorganic luminescent particles such as quantum dots (QDs) and quantum rods (QRs). The QDs and QRs are nano inorganic particles that emit light as electrons in an unstable state fall from the conduction band energy level to the valence band energy level.

In one embodiment, the inorganic luminescent particles can have a single structure. In another embodiment, the inorganic luminescent particles can have a heterogeneous structure of core/shell, and can comprise plural organic ligands that are bound to the surface of the core or free from the inorganic luminescent particles. In this case, the shell can consist of one shell or comprise plural shells.

As an example, each of the EML1 340 and the EML3 540 can comprise quantum dots and/or quantum rods emitting blue light, and the EML2 440 can comprise quantum dots and/or quantum rods emitting red to green (if necessary yellow-green) lights.

Each of the ETL1 360, the ETL2 460 and the ETL3 560 transfers electrons to the EML1 340, the EML2 440 and the EML3 540, respectively. Each of the ETL1 360, the ETL2 460 and the ETL3 560 can independently comprise organic material or inorganic material. The ETIL 570 facilitates electron injections to the EML3 540 from the second electrode 220.

In FIG. 3, the LED D1 where three emitting parts 300, 400 and 500 form a tandem structure is illustrated, but the light emitting diode with a tandem structure is not limited thereto. As an example, an emissive layer constituting a light emitting diode with a tandem structure can consist of a first emitting part emitting blue light, a second emitting part emitting red to green (if necessary yellow green) lights, and a charge generation layer disposed between the first emitting part and the second emitting part. In another embodiment, the light emitting diode with the tandem structure can have four or more emitting parts. In this case, at least one emitting part can emit blue light, at least another emitting part can emit green light, and at least another emitting part can emit red light. If necessary, another emitting part can emit yellow green light.

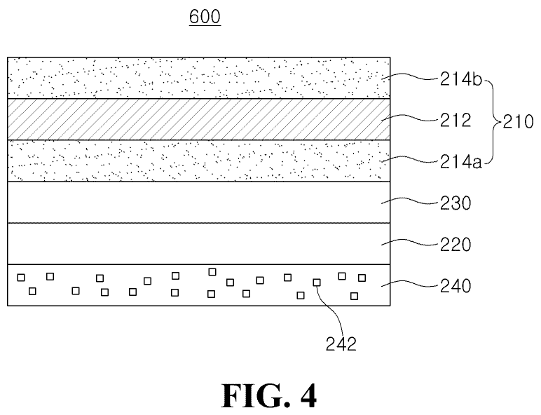

The structure of the polarizer 600 comprising a uniform dispersion phase retardation film will be described. FIG. 4 is a cross-sectional view illustrating a laminated structure of a polarizer in accordance with an embodiment of the present disclosure.

As illustrated in FIG. 4, the polarizer 600 can be a circular polarizer. The polarizer 600 can comprise a uniform dispersion phase retardation film 220 attached to outer surface of the second substrate 104 (FIG. 2) and a linear polarizer 210 disposed on the uniform dispersion phase retardation film 220. A first adhesive layer 230 is disposed been the uniform dispersion phase retardation film 230 and the linear polarizer 210 so that the uniform dispersion phase retardation film 220 can be attached to the linear polarizer 210. In addition, a second adhesive layer 240 is disposed between the second substrate 104 (FIG. 2) and the uniform dispersion phase retardation film 220 so that the uniform dispersion phase retardation film 220 can be attached to the second substrate 104. Each of the first adhesive layer 230 and the second adhesive layer 240 can independently comprise an optically transparent adhesive (OCA) or a pressure sensitive adhesive (PSA).

In one embodiment, a surface treatment layer can be disposed on an outer surface of the linear polarizer 210. For example, the surface treatment layer can be, but is not limited to, an anti-glare film comprising silica beads and/or a hard coating layer for preventing damages of the polarizer 600.

In one embodiment, the linear polarizer 210 can comprise a polarizing film 210 converting polarization property of light, and first and second protective films 214a and 214b disposed on both sides of the polarizing film 210 and protecting and supporting the polarizing film 210. The linear polarizer 210 absorbs linearly polarized light parallel to absorption axis of the polarizing film 212, and transmits linearly polarized light perpendicular to the absorption axis, that is, linearly polarized light parallel to the transmission axis of the polarizing film 212.

In one embodiment, the polarizing film 210 can comprise a stretched polyvinyl alcohol (PVA) dyed with iodine ions or dichroic dyes. In another embodiment, the polarizing film 212 can comprise reactive mesogens (RM) and dichroic dyes. In this case, the polarizing film 212 can further comprise an alignment layer to align the reactive mesogens and the dichroic dyes. Each of the first and second protective films 214a and 214b can be fabricated by stretching a film comprising tri-acetyl cellulose (TCA), polycarbonate (PC), polyethylene terephthalate (PET), or cyclic olefin polymer (COP).

In one embodiment, the uniform dispersion phase retardation film 220 can comprise a uniform dispersion quarter wave plate (QWP) that has a phase retardation of λ/4 and changes the polarization direction of incident light, and/or a uniform dispersion half wave plate (HWP) that has a phase retardation of λ/2 and changes the polarization direction of incident light. For example, linearly polarized light passing through the uniform dispersion QWP is converted into linearly polarized light rotated by 45 degrees, and linearly polarized light passing through the uniform dispersion HWP is converted into linearly polarized light rotated by 90 degrees.

For example, the uniform dispersion phase retardation film 220 can be fabricated by stretching a film a circular olefin polymer (COP), tri-acetyl cellulose (TCA), polycarbonate (PC) or polyethylene terephthalate (PET).

In addition, the first adhesive layer 230 and/or the second adhesive layer 240 can further comprise light scattering particles 242 as well as the adhesive. For example, the second adhesive layer 240 disposed between the second substrate 240 and the uniform dispersion phase retardation film 220 can comprise the light scattering particles 242. As the polarizer 600 includes the light scattering particles 244, the reflection visibility of the light emitting display device 100 (FIG. 2) can be further improved in case applying the uniform dispersion phase retardation film 220.

In one embodiment, the light scattering particles 240 can comprise any particles with a different refractive index (n) from the film materials in the polarizer 600. As an example, the light scattering particles 242 can comprise, but is not limited to, zirconium oxide (ZrO₂), titanium oxide (titania, TiO₂), aluminum oxide (alumina, Al₂O₃), zinc oxide ZnO), magnesium oxide (MgO), Indium-tin-oxide (ITO), aluminum-zinc-oxide (AZO), silicon oxide (silica, SiO₂) and/or combinations thereof. The light scattering particles 242 can have, but is not limited to, a circular shape or various polygonal shapes. The light scattering particles 242 can have, but is not limited to, a mean size of about 10 nm to about 100 μm. While the second adhesive layer 240 includes the light scattering particles 242 in FIG. 4, the first adhesive layer 230 can comprise the light scattering particles 242.

As the low-refractive light reduction lens 190 is disposed in the fourth pixel region SP4, hazard blue light amount can be blocked or lowered, and omnidirectional reflection visibility can be improved in the light emitting display device 100 comprising the uniform dispersion phase retardation film 220. In other words, light emitting display device 100 that the luminance, color gamut and correlation color temperature are not lowered, hazard blue light is effectively blocked and reflection visibility is improved, can be realized even if a low-priced uniform dispersion phase retardation film is applied instead of using an expensive reverse dispersion phase retardation film.

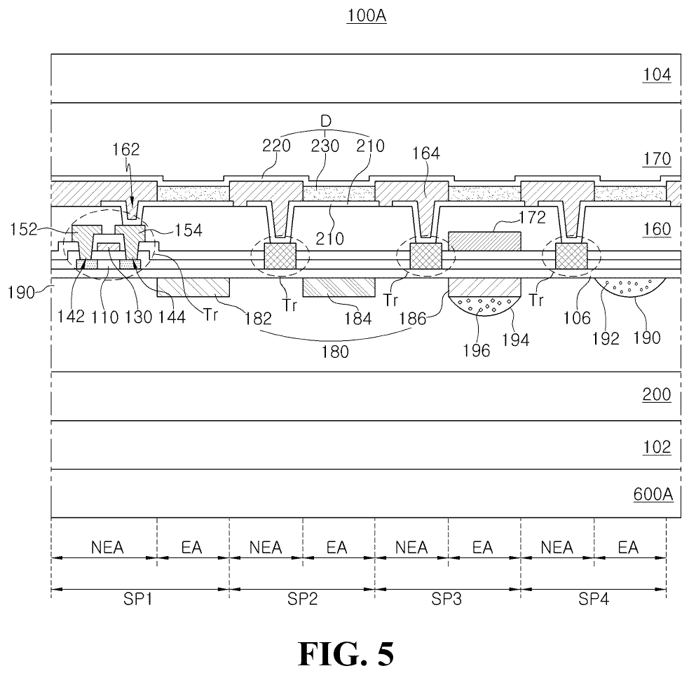

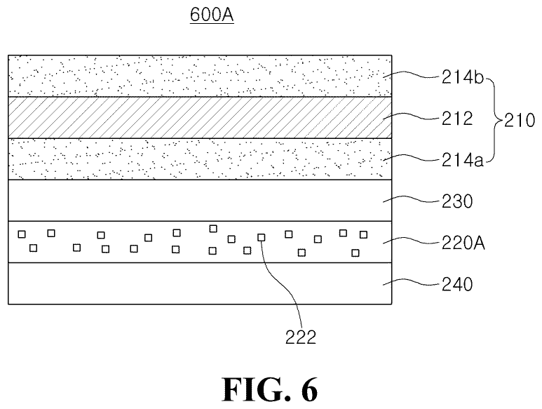

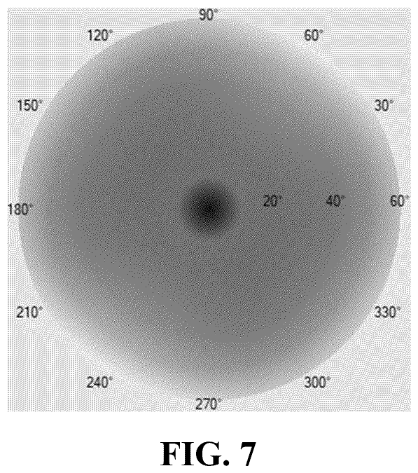

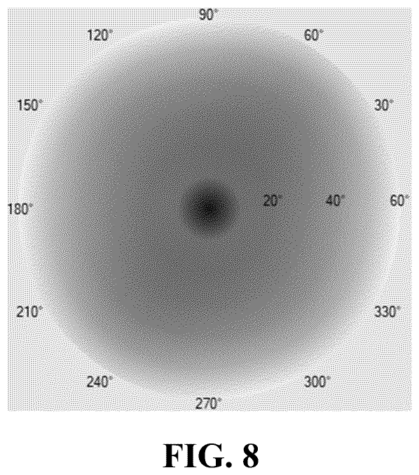

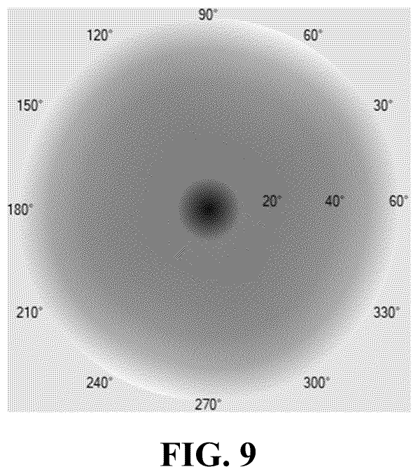

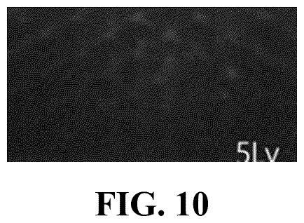

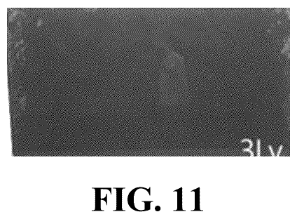

In FIGS. 2 to 4, the light emitted from the light emitting diode D is emitted to the second substrate 104 through the second electrode 220 and the color correction film 180. In other words, the light emitting display device 100 in FIGS. 2 to 4 is a top-emission type. Alternatively, the light emitting display device can have a bottom emission type where the light emitted from the light emitting diode D can be emitted to the first substrate 102 through the first electrode 210 (FIGS. 5 and 6).

Light emitting display device can further a light intensification lens disposed another pixel region as well as the light reduction lens. FIG. 5 illustrates a cross-sectional view of a light emitting display device in accordance another embodiment of the present disclosure.

As illustrated in FIG. 5, a light emitting display device 100A comprise a first substrate 102 in which defines a first to fourth pixel regions SP1, SP2, SP3 and SP4 each of which can be divided into an emission area EA and a non-emission area NEA, and a second substrate 104 facing the first substrate 102.

The light emitting display device 100A can comprise a thin film transistor Tr disposed on the first substrate 102 in each of the non-emission areas NEAs in the first to fourth pixel regions SP1, SP2, SP3 and SP4, and a light emitting diode D disposed correspondingly to each of the emission areas EAs in the first to fourth pixel areas SP1, SP2, SP3 and SP4 and connected to the thin film transistor Tr. As an example, the light emitting diode D can be a light emitting diode having the multiple emitting parts to form a tandem structure as illustrated in FIG. 3

A color correction pattern 180 and a light reduction lens 190 are disposed between the first substrate 102 and the light emitting diode D in the light emitting display device 100A unlike the light emitting display device 100 illustrated in FIG. 2. The light emitting display device 100A further comprises a light intensification lens 194 protruded toward to the first substrate 102 under a third color correction patter 186 disposed correspondingly to the third pixel region SP3. A second passivation layer 200 is disposed among a color correction pattern 180, the light reduction lens 192 and the light intensification lens 194, and the first substrate 102 with covering the entire surface of the first substrate 102, and a polarizer 600A is disposed under the first substrate 102. Other configurations can be substantially identical to the corresponding configurations illustrated in FIG. 2

For example, the light emitting display device 100A comprises the color correction pattern 180 disposed correspondingly to each of the emission area EAs in the first to third pixel regions SP1, SP2 and SP3, and disposed between the first substrate 102 and the light emitting diode D. In other embodiment, the color correction pattern 180 can be disposed correspondingly to each of the emission areas EAs in the first to third pixel regions SP1, SP2 and SP3, and can be disposed between the light emitting diode D and the thin film transistor Tr.

The color correction pattern 180 can comprise a first color correction pattern 182 disposed correspondingly to the emission area EA in the first pixel region SP1, a second color correction pattern 184 disposed correspondingly to the emission area EA in the second pixel region SP2 and a third color correction pattern 186 disposed correspondingly to the emission area EA in the third pixel region SP3.

In one embodiment, each of the first to third color correction patterns 182, 184 and 186 can comprises one or more red colorants, one or more green colorants and one or more blue colorants, respectively. Each of the first to third color correction patterns 182, 184 and 186 can be a color filter pattern transmitting a specific light among white (W) light emitted from the light emitting diode D. In another embodiment, each of the first to third color correction patterns 182, 184 and 186 can comprise red quantum dots and/or red quantum rods, green quantum dots and/or green quantum rods and blue quantum dots and/or blue quantum rods, respectively. Each of the first to third color correction patterns 182, 184 and 186 can be a color conversion pattern converting white (W) light emitted from the light emitting diode D to a specific color light.

The light reduction lens 190 disposed between the thin film transistor Tr and the first substrate 102 in the fourth pixel region SP4 can comprise a low-refractive material 192 with a refractive index of about 1.30 to about 1.50. For example, the light reduction lens 192 can have a shape protruding toward the light emission direction, that is, toward to the first substrate 102 from the light emitting diode D. As an example, the light reduction lens 190 can have, but is not limited to, a semicircular shape or a semielliptical shape protruding toward the first substrate 102 from the light emitting diode D. The light reduction lens 190 enables the hazard blue light to be blocked or lowered.

The light intensification lens 194 can be disposed correspondingly to the third color correction pattern 186 disposed in the emission area EA of the third pixel region SP3 that can be a blue pixel region. The light intensification lens 194 can have a shape protruding toward the light emission direction, that is, toward the first substrate 102 from the third color correction pattern 186. As an example, the light intensification lens 194 can have, but is not limited to, a semicircular shape or a semielliptical shape protruding toward the first substrate 102 from the third color correction pattern 186.

The light intensification lens 194 can comprise a high-refractive material 196. For example, the high-refractive material 196 can have a refractive index (n) of about 1.65 to about 2.50, for example, about 1.65 to about 2.7 or about 1.67 to about 1.90. The blue (B) light emitted from the third color correction pattern 186 can be diffused in the light intensification lens 194 comprising the high-refractive material 196. Accordingly, the blue light luminance in the light emitting display device 100A can be further improved.

In one embodiment, the high-refractive material 196 in the light intensification lens 194 can comprise an inorganic material such as ZrO₂, TiO₂, Al₂O₃, ZnO, MgO, ITO, AZO, SiO₂ and/or combinations thereof. In another embodiment, the high-refractive material 196 can comprise one or more polymers. The polymer that can be applied to the high-refractive material 196 can comprise, but is not limited to, poly(alpha-naphthyl-methacrylate), poly(beta-naphthyl-methacryalte), poly(2-vinylthiophene, poly sulfone, poly(vinyl phenyl sulfide), poly(styrene sulfide), poly(2-vinylnaphthalene), copolymers thereof and combinations thereof.

The structure of the polarizer 600A disposed on the outside of the first substrate 102 will be described. FIG. 6 is a cross-sectional view illustrating a laminated structure of a polarizer in accordance with another embodiment of the present disclosure.

As illustrated in FIG. 6, the polarizer 600A can be a circular polarizer for blocking external light. The polarizer 600A can comprise a uniform dispersion phase retardation film 220A attached onto the outer surface of the first substrate 102 (FIG. 5) and a linear polarizer 210 disposed on the uniform dispersion phase retardation film 220A. The polarizer 600A can comprise a first adhesive layer 230 disposed between the linear polarizer 210 and the uniform dispersion phase retardation film 220A and a second adhesive layer 240 disposed between the first substrate 102 (FIG. 5) and the uniform dispersion phase retardation film 220A.

The linear polarizer 210 can comprise a polarizing film 210 converting polarization property of light, and first and second protective films 214a and 214b disposed on both sides of the polarizing film 210 and protecting and supporting the polarizing film 210. The polarizing film 210 can comprise a stretched polyvinyl alcohol (PVA) dyed with iodine ions and/or dichroic dyes, or can comprise reactive mesogens (RM) and dichroic dyes. Each of the first and second protective films 214a and 214b can be fabricated by stretching a film comprising tri-acetyl cellulose (TCA), polycarbonate (PC), polyethylene terephthalate (PET), and/or cyclic olefin polymer (COP).

The uniform dispersion phase retardation film 220A can comprise a uniform dispersion quarter wave plate (QWP) and/or a uniform dispersion half wave plate (HWP). The uniform dispersion phase retardation film 220A can be fabricated by stretching a film a circular olefin polymer (COP), tri-acetyl cellulose (TCA), polycarbonate (PC) and/or polyethylene terephthalate (PET).

The uniform dispersion phase retardation film 220A comprises light scattering particles 222 as well as the COP, TCA, PC and/or PET. As the polarizer 600A comprise the light scattering particles 222, the reflection visibility of the light emitting display device 100A (FIG. 5) can be further improved even if the uniform dispersion phase retardation film 220A is applied to the device 100A. As an example, the light scattering particles 222 can be identical to the light scattering particles 242 with referring to FIG. 4.

As the low-refractive light reduction lens 190 is disposed in the fourth pixel region SP4, hazard blue light amount can be blocked or lowered, and omnidirectional reflection visibility can be improved in the light emitting display device 100A comprising the uniform dispersion phase retardation film 220A. The blue light luminance can be further improved as the high-refractive light intensification lens 194 is applied to the third pixel region SP3. Accordingly, the light emitting display device 100A that the luminance, color gamut and correlation color temperature are not lowered, hazard blue light is effectively blocked and reflection visibility is improved, can be realized even if a low-priced uniform dispersion phase retardation film is applied instead of using an expensive reverse dispersion phase retardation film.

### Example 1 (Ex. 1): Fabrication of Light Emitting Display Device

A light emitting display device where a thin film transistor and a white organic light emitting diode were disposed in each of a first pixel region (red pixel region), a second pixel region (green pixel region), a third pixel region (blue pixel region) and a fourth pixel region (white pixel region). A color filter layer comprising a red colorant, a green colorant and a blue colorant was disposed correspondingly to each of the organic light emitting diodes disposed in the first to third pixel regions, respectively. A polarizer comprising a uniform dispersion λ/4 phase retardation film and a linear polarizer was attached onto a substrate disposed located in a direction of light emission. An adhesive layer consisting of light scattering particles TiO₂ particles dispersed in a pressure sensitive adhesive disposed between the λ/4 phase retardation film and the linear polarizer to attach the polarizer to the substrate. A semicircular shape light reduction lens protruded toward the light emission direction with material with a refractive index of 1.30-1.50 was disposed on the light emitting diode in the fourth pixel region.

### Example 2 (Ex. 2): Fabrication of Light Emitting Display Device

A light emitting display device was fabricated as the same process as Example 1, except that a semicircular shape light intensification lens protruded toward the light emission direction with material with a refractive index of 1.65-2.0 was disposed on the color filter layer in the third pixel region.

### Comparative Example 1 (Ref. 1): Fabrication of Light Emitting Display Device

A light emitting display device was fabricated as the same process as Example 1, except that the light reduction lens was not disposed in the fourth pixel region.

Comparative Example 2 (Ref. 2): Fabrication of Light Emitting Display Device

A light emitting displace was fabricated as the same process as Example 1, except that the adhesive layer of the pressure sensitive adhesive disposed between he λ/4 phase retardation film and the linear polarizer did not comprise the light scattering particles.

### Experimental Example 1: Evaluation of omnidirectional Visibility and Reflectivity

Omnidirectional visibility and reflectivity in the light emitting display devices fabricated in Examples 1 and 2, and Comparative Example 1 was evaluated. Evaluation Results are illustrated in FIG. 7 (Comparative Example 1), FIG. 8 (Example 1), FIG. 9 (Example 2) and the following Tables 1 and 2.

TABLE 1
Frontal Reflectivity (2 degree)

| Reflectivity | Ref. 1 | Ex. 1 | Ex. 2 |
|---|---|---|---|
| 550 nm | 1.83 | 1.85 | 1.84 |
| Y | 2.0 | 2.0 | 2.0 |
| a* | 6.1 | 0.7 | 0.6 |
| b* | −15 | −3.9 | −3.7 |

TABLE 2
Viewing Angle Reflectivity (40 degree)

| Reflectivity | Ref. 1 | Ex. 1 | Ex. 2 |
|---|---|---|---|
| 550 nm | 1.83 | 1.85 | 1.84 |
| Y | 2.0 | 2.0 | 2.0 |
| a* | 6.1 | 0.7 | 0.6 |
| b* | −15 | −3.9 | −3.7 |

As illustrated in FIGS. 7 to 9 and Tables 1 and 2, the omnidirectional visibility and reflectivity property in the light emitting display device fabricated in Examples 1 and 2 was significantly improved.

### Experimental Example 2: Evaluation of Frontal Visibility

Frontal visibility in the light emitting display device fabricated in Example 1 and Comparative Example 1 by the presence of the light scattering particles was evaluated. Evaluation Results are illustrated in FIG. 10 (Comparative Example 2) and FIG. 11 (Example 1). The frontal visibility was significantly improved as the light scattering particles are applied into the light emitting display device.

### Experimental Example 3: Evaluation of Blue Light and Whole Light Property

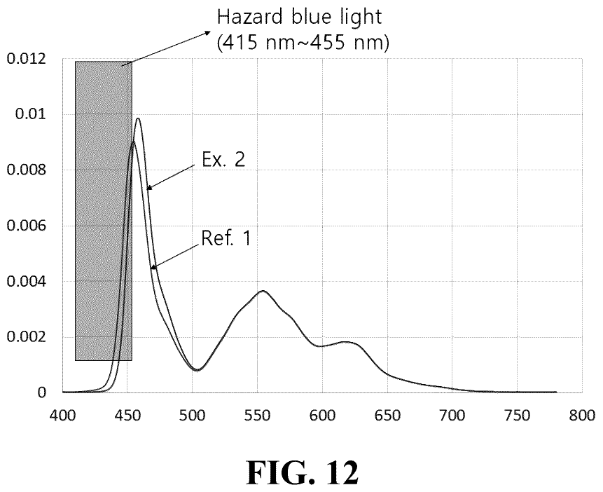

Blue light and panel whole light properties in the light emitting display devices fabricated in Examples 1 and 2, and Comparative Example 1 was evaluated. The evaluation Results are illustrated in FIG. 12 and the following Table 3. BLR was calculated by the following Equation (1):

$$BLR ( \% ) = ( intensity of 415 - 450 nm ) / ( intensity of 400 - 500 nm ) \qquad ( 1 )$$

TABLE 3
Blue Light and Whole Light Property

| Sample | BLR | CCT | Luminance (cd/m²) | C/G |
|---|---|---|---|---|
| Ref. 1 | 37% (Level 3) | 10150K | 200 | 99.1% |
| Ex. 1 | 25.5% (Level 2) | 9985K | 200 | 99.1% |
| Ex. 2 | 25.5% (Level 2) | 9985K | 202 | 99.1% |

As illustrated in Table 3 and FIG. 12, the luminance, the correlated color temperature (CCT) and color gamut (C/G) in the light emitting display device fabricated in Examples 1 and 2 was high. Particularly, the emitted amount of hazard blue light was reduced significantly in the light emitting display device fabricated in Examples 1 and 2.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A light emitting display device, comprising:
a light emitting diode disposed at each of emission areas of a first pixel region, a second pixel region, a third pixel region, and a fourth pixel region;
a color correction pattern, wherein light emitted from the light emitting diode is respectively disposed in the first pixel area, the second pixel area, and the third pixel area;
a light reduction lens located in a direction in which the light from the light emitting diode disposed in the fourth pixel area is emitted;
a substrate disposed in a direction in which the light from the light emitting diode is emitted relative to the color correction pattern and the light reduction lens; and
a polarizer disposed on an outer surface of the substrate, comprising a uniform dispersion phase retardation film,
wherein the light reduction lens has a shape protruding from the light emitting diode disposed in the fourth pixel region toward the substrate.

2. The light emitting display device of claim 1, wherein the light reduction lens comprises a material with a refractive index of about 1.30 to about 1.50.

3. The light emitting display device of claim 1, wherein the light emitting display device further comprises a light intensification lens disposed between the color correction pattern disposed respectively to the third pixel region and the substrate, and wherein the light emitting display device has a shape protruding from the color correction pattern disposed in the third pixel region toward the substrate.

4. The light emitting display device of claim 3, wherein the light intensification lens comprises a material with a refractive index of about 1.65 to about 2.50.

5. The light emitting display device of claim 3, wherein the light intensification lens has a semicircular shape or a semielliptical shape protruding the color correction film disposed respectively to the third pixel region toward the substrate.

6. The light emitting display device of claim 1, wherein the uniform dispersion phase retardation film comprises at least one of a quarter wave plate (QWP) and a half wave plate (HWP).

7. The light emitting display device of claim 1, wherein the polarizer further comprises a linear polarizer attached to the uniform dispersion phase retardation film.

8. The light emitting display device of claim 1, wherein the linear polarizer comprises:
a polarizing film; and
a first protective film and a second protective film disposed on both sides of the polarizing film.

9. The light emitting display device of claim 8, wherein the polarizer further comprises:
a first adhesive layer disposed between the linear polarizer and the uniform dispersion phase retardation film; and
a second adhesive layer disposed between the uniform dispersion phase retardation film and the substrate.

10. The light emitting display device of claim 9, wherein at least one of the first adhesive layer and the second adhesive layer comprises light scattering particles.

11. The light emitting display device of claim 10, wherein the light scattering particles are chosen from ZrO₂, TiO₂, Al₂O₃, ZnO, MgO, Indium-tin-oxide (ITO), aluminum-zinc-oxide (AZO), SiO₂, and combinations thereof.

12. The light emitting display device of claim 1, wherein the uniform dispersion phase retardation film comprises light scattering particles.

13. The light emitting display device of claim 12, wherein the light scattering particles are chosen from ZrO₂, TiO₂, Al₂O₃, ZnO, MgO, Indium-tin-oxide (ITO), aluminum-zinc-oxide (AZO), SiO₂, and combinations thereof.

14. The light emitting display device of claim 1, wherein the light emitting diode comprises:
a first electrode;
a second electrode facing the first electrode; and
an emissive layer disposed between the first electrode and the second electrode,
wherein the emissive layer comprises one or more emitting material layers.

15. The light emitting display device of claim 1, wherein the light emitting display device further comprises a thin film transistor disposed on the substrate respectively to each of non-emission areas of the first pixel region, the second pixel region, the third pixel region, and the fourth pixel region, wherein the thin film transistor is connected to the light emitting diode respectively to the first pixel region, the second pixel region, the third pixel region, and the fourth pixel region.

16. The light emitting display device of claim 1, wherein the first pixel region is a red pixel region, the second pixel region is a green pixel region, the third pixel region is a blue pixel region, and the fourth pixel region is a white pixel region.

17. The light emitting display device of claim 1, wherein the light reduction lens has a semicircular shape or a semielliptical shape protruding the light emitting diode toward the substrate.

18. The light emitting display device of claim 1, wherein the color correction pattern comprises a colorant.

19. The light emitting display device of claim 1, wherein the color correction pattern comprises inorganic luminescent particles.
